(19) United States
(12) Patent Application Publication
(10) Pub. No.: US 2023/0068596 A1
(43) Pub. Date: Mar. 2, 2023

(54) PORTABLE GAS WATER MAKER BASED ON PELTIER THERMOELECTRIC EFFECT, AND WATER-MAKING METHOD THEREOF

(71) Applicant: XIJING UNIVERSITY, Xi 'an (CN)

(72) Inventors: Kai CHEN, Xi 'an (CN); Qian ZHANG, Xi 'an (CN); Yao QIN, Xi 'an (CN); Xinfei LIU, Xi 'an (CN); Chenbo ZHANG, Xi 'an (CN); Wei ZHANG, Xi 'an (CN)

(73) Assignee: XIJING UNIVERSITY, Xi 'an (CN)

(21) Appl. No.: 17/893,204

(22) Filed: Aug. 23, 2022

(30) Foreign Application Priority Data
Aug. 24, 2021 (CN) 202110972329.4

(51) Int. Cl. F25B 21/02; F24H 8/00; E03B 3/28; H01L 35/32

(52) U.S. Cl. CPC F25B 21/02; F24H 8/006; E03B 3/28; H01L 35/32

(57) ABSTRACT

A portable gas water maker comprises a water maker body with a shell having a hollow structure. A water inlet communicating with the shell and used for injecting water into the shell is formed at an upper end of the water maker body. The water maker body is inverted U-shaped, so that the lower half part of the water maker body is divided into a left cavity and a right cavity. One group of Peltier semiconductor assemblies is arranged in each of the left cavity and the right cavity. A front-end semiconductor and a rear-end semiconductor in each group of Peltier semiconductor assemblies are connected through a wire. The group of semiconductor assemblies in the left cavity is used for generating electricity, and the group of semiconductor assemblies in the right cavity is used for refrigeration.

### CROSS REFERENCES OF THE RELATED APPLICATIONS

The present application is based upon and claims priority to Chinese Patent Application No. 202110972329.4, filed on Aug. 24, 2021, the entire contents of which are hereby incorporated by reference.

### TECHNICAL FIELD

The present invention belongs to the technical field of water makers, and particularly relates to a portable gas water maker based on the Peltier thermoelectric effect, and a water-making method.

### BACKGROUND

At present, most water makers on the market are either air water makers or wind water makers.

Here is how the air water maker works: when a refrigerating system operates normally, a liquid refrigerant entering an evaporator evaporates to make the temperature lower than the dew point temperature of wet air passing through the evaporator, and when the liquid refrigerant evaporates in the evaporator, the liquid refrigerant absorbs heat from the air to reduce the temperature of the air to below the dew point temperature, and then condensed water is formed on the surface of the evaporator; the condensed water is filtered, purified and disinfected to obtain up-to-standard drinking water.

The wind water maker cures, to some extent, the defect that common water makers cannot make water outdoors. It works substantially the same way as the air water maker. Both of them make water from the water molecules in the air. Improvements are made to only the power source.

At present, the water makers in China mainly supply electric power required by the operation of a condenser through an external power supply to form cold and hot convection, and water in the air is condensed and filtered to obtain daily drinking water. Under ideal conditions, the air water maker requires a water content of 50% or more in the air to achieve the optimal water-making performance. However, in general, the water content in the air is less than 0.03%, resulting in low water-making efficiency. Moreover, because the existing water makers all need an external power supply to provide electric power, the water makers cannot normally work in some outdoor environments without electric power supply.

### SUMMARY

An objective of the present invention is to provide a portable gas water maker based on the Peltier thermoelectric effect, and a water-making method thereof, wherein no external power supply is needed; a large amount of water vapor generated in the gas combustion process is condensed, collected and utilized by using the Peltier thermoelectric effect, so that the use efficiency and the portability of the water maker are improved.

In order to achieve the above objective, the present invention adopts the following technical solutions.

A portable gas water maker based on the Peltier thermoelectric effect comprises a water maker body with a shell having a hollow structure, wherein a water inlet communicating with the shell and used for injecting water into the shell is formed at an upper end of the water maker body.

The water maker body is inverted U-shaped, so that the lower half part of the water maker body is divided into a left cavity and a right cavity, and both the left cavity and the right cavity communicate with the interior of the water maker body to form a flue for flue gas to flow through.

One group of Peltier semiconductor assemblies are arranged in each of the left cavity and the right cavity of the water maker body, and a front-end semiconductor and a rear-end semiconductor in each group of Peltier semiconductor assemblies are connected through a wire; a front-end semiconductor arrange on the inner left side of the left cavity is connected to a rear-end semiconductor arranged on the inner right side of the right cavity through a wire, and a rear-end semiconductor arranged on the inner right side of the left cavity is connected to a front-end semiconductor arranged on the inner left side of the right cavity through a wire; the group of semiconductor assemblies in the left cavity are used for generating electricity, and the group of semiconductor assemblies in the right cavity are used for refrigeration.

A flue gas inlet is formed at the bottom of the left cavity, and a flue gas outlet and a water outlet are formed at the bottom of the right cavity; high-temperature flue gas enters the flue in the water maker body through the flue gas inlet and forms a temperature difference with water in the shell of the water maker body, so that one group of Peltier semiconductor assemblies generate electricity through the temperature difference and supply current to the other group of Peltier semiconductor assemblies for refrigeration, and thus the high-temperature flue gas in the flue is condensed to obtain liquid water and low-temperature flue gas, and the low-temperature flue gas and the liquid water are discharged through the water outlet and the flue gas outlet.

Further, small finned radiators are mounted on the Peltier semiconductor assemblies.

Further, a filtering device is arranged in a pipeline connecting the flue gas inlet and the interior of the water maker body.

Further, a safety valve communicating with the water maker body is arranged at the upper end of the water maker body.

Further, the water outlet and the flue gas outlet are the same outlet.

A water-making method of a portable gas water maker based on the Peltier thermoelectric effect comprises the following steps:

Step 1: inspecting the tightness of the water maker body and various pipelines, inspecting the air tightness and safety of the safety valve, inspecting the safety of external fuel gas, and inspecting the connection condition of wires;

igniting the fuel gas after passing the inspection, and introducing high-temperature flue gas into a flue formed in the water maker body through the flue gas inlet;

Step 2: after the flue gas enters the water maker body, forming a temperature difference between the flue gas that is at a very high temperature and the water in the shell of the water maker body, then enabling one group of Peltier semiconductor assemblies to generate electricity, and supplying current to the other group of Peltier semiconductor assemblies to achieve the Peltier effect, namely semiconductor refrigeration;

Step 3: condensing the high-temperature flue gas in the flue to obtain liquid water and low-temperature flue gas, and discharging the low-temperature flue gas out of the water maker from the flue gas outlet and into the atmosphere; and

Step 4: enabling the liquid water obtained in step 3 to flow out through the water outlet for users to use.

Compared with the prior art, the present invention has the following advantages.

After the high-temperature flue gas enters the water maker body, because the temperature of the flue gas is very high, the flue gas and water filled in the hollow structure of the shell of the water maker form a temperature difference, and one group of Peltier semiconductor assemblies arranged in the water maker body generate electricity through the temperature difference and supply current to the other group of Peltier semiconductor assemblies to achieve the Peltier effect, namely semiconductor refrigeration, so that the high-temperature flue gas is condensed to obtain liquid water and low-temperature flue gas, and the low-temperature flue gas and the liquid water are discharged through the water outlet and the flue gas outlet; and an external power supply is not needed, which favors the use of the water maker in places where electrical energy is lacking. Meanwhile, liquid water is obtained after the high-temperature flue gas is condensed, and a traditional heat pump is not needed, so that the water-making efficiency is improved, and the water maker is smaller in size and easy to carry; in addition, the fuel gas is compressible, small in volume and lightweight, making it easier to carry the water maker.

The small finned radiators are arranged on the semiconductor assemblies, reducing the possibility of the semiconductor material not working normally due to damage caused by high temperature, and thus prolonging the service life of the water maker.

The filtering device is arranged in the pipeline connecting the flue gas inlet and the interior of a water tank shell of the water maker body, so that the condensed water is cleaner and contains fewer impurities.

The safety valve is arranged on the water tank shell of the water maker body to prevent the water tank shell from failing due to high temperature.

### BRIEF DESCRIPTION OF THE DRAWINGS

FIG. 1 is a structural schematic diagram according to the present invention;

FIG. 2 is a bottom view according to the present invention;

FIG. 3 is a front view of a small finned radiator according to the present invention;

FIG. 4 is a bottom view of a small finned radiator according to the present invention;

and

FIG. 5 is a side view of a small finned radiator according to the present invention.

In the drawings, 1. water maker body; 2. Peltier semiconductor assembly; 3. small finned radiator; 4. water inlet; 5. safety valve; 6. wire; 7. flue gas inlet; 8. flue gas outlet and water outlet.

### DETAILED DESCRIPTION OF THE EMBODIMENTS

The specific content of the present invention is further illustrated in detail below with reference to the examples, to which, however, the present invention is not limited.

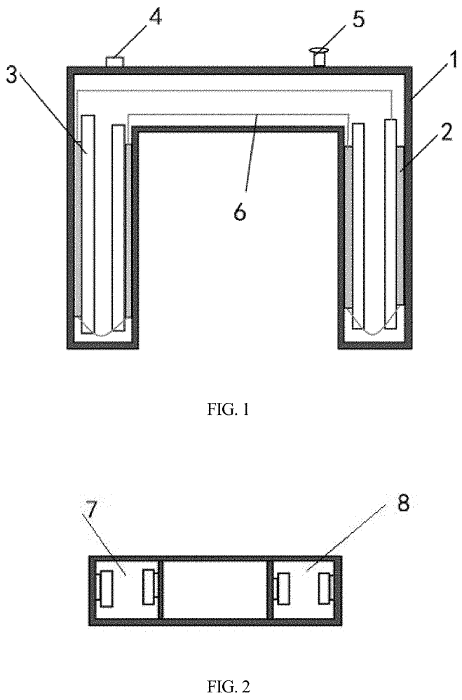

As shown in FIG. 1 and FIG. 2, a portable gas water maker based on the Peltier thermoelectric effect comprises a water maker body 1 with a shell having a hollow structure, wherein a water inlet 4 communicating with the shell and used for injecting water into the hollow structure is formed at an upper end of the water maker body 1; the water maker body 1 is inverted U-shaped, so that the lower half part of the water maker body is divided into a left cavity and a right cavity, and both the left cavity and the right cavity communicate with the interior of the water maker body 1 to form a flue for flue gas to flow through.

One group of Peltier semiconductor assemblies 2 are arranged in each of the left cavity and the right cavity of the water maker body 1, a front-end semiconductor in each group of semiconductor assembly is attached to a left side wall of the cavity where the front-end semiconductor is located, a rear-end semiconductor is attached to a right side wall of the cavity where the rear-end semiconductor is located, and the front-end semiconductor and the rear-end semiconductor in the same cavity are connected through a wire; the front-end semiconductor in the left cavity is connected to the rear-end semiconductor in the right cavity through a wire, and the rear-end semiconductor in the left cavity is connected to the front-end semiconductor in the right cavity through a wire; the group of semiconductor assemblies 2 in the left cavity are used for generating electricity, and the group of semiconductor assemblies 2 in the right cavity are used for refrigeration.

A flue gas inlet 7 is formed at the bottom of the left cavity, and a filtering device is arranged at the flue gas inlet 7, so that condensed water is cleaner and contains fewer impurities;

A flue gas outlet and a water outlet 8 are formed at the bottom of the right cavity; high-temperature flue gas enters the water maker body 1 through the flue gas inlet 7 and forms a temperature difference with water in the shell of the water maker body, so that one group of Peltier semiconductor assemblies 2 generates electricity through the temperature difference and supplies current to the other group of Peltier semiconductor assemblies 2 to achieve the Peltier effect, namely semiconductor refrigeration, and the high-temperature flue gas is condensed to obtain liquid water and low-temperature flue gas, and the low-temperature flue gas and the liquid water are discharged through the water outlet and the flue gas outlet.

Preferably, the water outlet and the flue gas outlet are the same outlet.

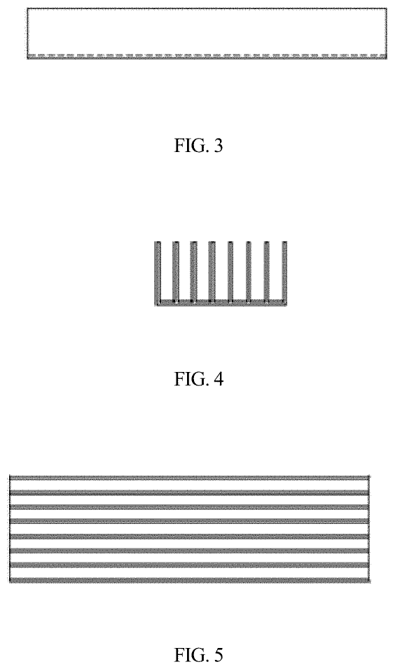

As shown in FIG. 1, FIG. 2, FIG. 3, FIG. 4 and FIG. 5, small finned radiators 3 are mounted on the two groups of Peltier semiconductor assemblies 2, so that heat dissipation of the Peltier semiconductor assemblies 2 can be accelerated, the possibility of the semiconductor assemblies 2 not working normally due to damage caused by high temperature is reduced, and the service life of the water maker is prolonged.

As shown in FIG. 1, a safety valve 5 is arranged on a water tank shell of the water maker body 1, and the safety valve 5 communicates with the interior of the water tank shell of the water maker body 1 to prevent the water tank shell from failing due to high temperature.

A water-making method of a portable gas water maker based on the Peltier thermoelectric effect comprises the following steps:

Step 1: inspecting the tightness of the water maker body 1 and various pipelines, inspecting the air tightness and safety of the safety valve 5, inspecting the safety of external fuel gas, and inspecting the connection condition of wires 6;

igniting the fuel gas after passing the inspection, and introducing high-temperature flue gas into a flue formed in the water maker body 1 through the flue gas inlet 7;

Step 2: after the flue gas enters the water maker body 1, forming a temperature difference between the flue gas that is at a very high temperature and the water in the shell of the water maker body 1, then enabling one group of Peltier semiconductor assemblies 2 to generate electricity, and supplying current to the other group of Peltier semiconductor assemblies 2 to achieve the Peltier effect, namely semiconductor refrigeration;

Step 3: condensing the high-temperature flue gas in the flue to obtain liquid water and low-temperature flue gas, and discharging the low-temperature flue gas out of the water maker from the flue gas outlet and into the atmosphere; and

Step 4: enabling the liquid water obtained in step 3 to flow out through the water outlet for users to use.

The present invention works in the following way.

External high-temperature flue gas is introduced into the flue formed in the water maker body 1 through the flue gas inlet 7, and the high-temperature flue gas forms a temperature difference with the water in the shell of the water maker body, so that one group of Peltier semiconductor assemblies 2 generate electricity through the temperature difference and supply current to the other group of Peltier semiconductor assemblies 2 to achieve the Peltier effect, namely semiconductor refrigeration, and the high-temperature flue gas is condensed to obtain liquid water and low-temperature flue gas, and the low-temperature flue gas is discharged from the flue gas outlet and the liquid water is discharged from the water outlet for users to use.

1. A portable gas water maker based on Peltier thermoelectric effect, comprising a water maker body with a shell having a hollow structure, wherein a water inlet communicating with the shell and used for injecting water into the shell is formed at an upper end of the water maker body;
the water maker body is inverted U-shaped, the lower half part of the water maker body is divided into a left cavity and a right cavity, and both the left cavity and the right cavity communicate with the interior of the water maker body to form a flue for flue gas to flow through;
a first group of Peltier semiconductor assemblies and a second group of Peltier semiconductor assemblies are respectively arranged in the left cavity and the right cavity of the water maker body, and a first front-end semiconductor and a first rear-end semiconductor in each of the first and second groups of Peltier semiconductor assemblies are connected through a first wire;
a second front-end semiconductor arranged on an inner left side of the left cavity is connected to a second rear-end semiconductor arranged on an inner right side of the right cavity through a second wire, and a third rear-end semiconductor arranged on the inner right side of the left cavity is connected to a third front-end semiconductor arranged on the inner left side of the right cavity through a third wire;
the first group of semiconductor assemblies in the left cavity is used for generating electricity, and the second group of semiconductor assemblies in the right cavity is used for refrigeration;
a flue gas inlet is formed at a bottom of the left cavity, and a flue gas outlet and a water outlet are formed at a bottom of the right cavity;
high-temperature flue gas enters the flue in the water maker body through the flue gas inlet and forms a temperature difference with water in the shell of the water maker body, the first group of Peltier semiconductor assemblies generates electricity through the temperature difference and supplies current to the second group of Peltier semiconductor assemblies for refrigeration, and the high-temperature flue gas in the flue is condensed to obtain liquid water and low-temperature flue gas, and the low-temperature flue gas and the liquid water are discharged through the water outlet and the flue gas outlet.

2. The portable gas water maker based on the Peltier thermoelectric effect according to claim 1, wherein small finned radiators are mounted on each of the first and second groups of Peltier semiconductor assemblies.

3. The portable gas water maker based on the Peltier thermoelectric effect according to claim 1, wherein a filtering device is arranged in a pipeline connecting the flue gas inlet and an interior of the water maker body.

4. The portable gas water maker based on the Peltier thermoelectric effect according to claim 2, wherein a filtering device is arranged in a pipeline connecting the flue gas inlet and an interior of the water maker body.

5. The portable gas water maker based on the Peltier thermoelectric effect according to claim 1, wherein a safety valve communicating with the water maker is arranged at the upper end of the water maker body.

6. The portable gas water maker based on the Peltier thermoelectric effect according to claim 2, wherein a safety valve communicating with the water maker is arranged at the upper end of the water maker body.

7. The portable gas water maker based on the Peltier thermoelectric effect according to claim 1, wherein the water outlet and the flue gas outlet are the same outlet.

8. The portable gas water maker based on the Peltier thermoelectric effect according to claim 2, wherein the water outlet and the flue gas outlet are the same outlet.

9. A water-making method using the portable gas water maker according to claim 5, comprising the following steps:
step 1: inspecting tightness of the water maker body and various pipelines, inspecting air tightness and safety of the safety valve, inspecting safety of external fuel gas, and inspecting a connection condition of the first, second and third wires;
igniting the external fuel gas after passing the inspection, and introducing high-temperature flue gas into the flue formed in the water maker body through the flue gas inlet;
step 2: after the high-temperature flue gas enters the water maker body, forming the temperature difference between the high-temperature flue gas and the water in the shell of the water maker body, then enabling the first group of Peltier semiconductor assemblies to generate electricity, and supplying current to the second group of Peltier semiconductor assemblies to achieve the Peltier thermoelectric effect, to further achieve semiconductor refrigeration;
step 3: condensing the high-temperature flue gas in the flue to obtain the liquid water and the low-temperature flue gas, and discharging the low-temperature flue gas out of the portable gas water maker from the flue gas outlet and into the atmosphere; and
step 4: enabling the liquid water obtained in step 3 to flow out through the water outlet for users to use.
